(19) United States
(12) Patent Application Publication
(10) Pub. No.: US 2023/0353170 A1
(43) Pub. Date: Nov. 2, 2023

(54) RADIO FREQUENCY CIRCUIT AND COMMUNICATION DEVICE

(71) Applicant: Murata Manufacturing Co., Ltd., Nagaokakyo-shi (JP)

(72) Inventors: Hirotsugu MORI, Nagaokakyo-shi (JP); Hidenori OBIYA, Nagaokakyo-shi (JP); Tomohiro SANO, Nagaokakyo-shi (JP)

(73) Assignee: Murata Manufacturing Co., Ltd., Nagaokakyo-shi (JP)

(21) Appl. No.: 18/349,179

(22) Filed: Jul. 10, 2023

Related U.S. Application Data
(63) Continuation of application No. PCT/JP2022/000307, filed on Jan. 7, 2022.

(30) Foreign Application Priority Data
Jan. 13, 2021 (JP) 2021-003553

(51) Int. Cl. H04B 1/00; H04L 5/14

(52) U.S. Cl. CPC H04B 1/0057; H04L 5/14

(57) ABSTRACT

A radio frequency circuit includes: a first filter connected to an antenna connection terminal and having a passband including a first band; a second filter connected to the antenna connection terminal and having a passband including a second band; and an active circuit connected to the first filter. The active circuit includes: a low noise amplifier; a first capacitor disposed on a feedback path of the low noise amplifier; and at least one of a first inductor or a first resistor, disposed on the feedback path. A signal of the first band and a signal of the second band are simultaneously transferable.

### CROSS-REFERENCE TO RELATED APPLICATIONS

This is a continuation application of PCT International Application No. PCT/JP2022/000307 filed on Jan. 7, 2022, designating the United States of America, which is based on and claims priority to Japanese Patent Application No. 2021-003553 filed on Jan. 13, 2021. The entire contents of the above-identified applications, including the specifications, drawings and claims, are incorporated herein by reference in their entirety.

### TECHNICAL FIELD

The present disclosure relates to a radio frequency (RF) circuit and a communication device.

### BACKGROUND

For radio frequency circuits that support multiband and multimode, there is a need to transfer and receive a plurality of radio frequency signals with low loss and high isolation.

US Patent Application Publication No. US 2016/0127015 A1 discloses a receiving module (transfer circuit) having a configuration in which a plurality of filters with different passbands are connected to an antenna via a multiplexer (switch).

### SUMMARY

### Technical Problems

In the 3rd generation partnership project (3GPP), for example, a simultaneous transfer (EN-DC: E-UTRAN New Radio-Dual Connectivity) mode for simultaneously transferring a radio frequency signal of the 5th generation (5G)-new radio (NR) band and a radio frequency signal of the 4th generation (4G)-long term evolution (LTE) band is required.

In a radio frequency circuit that supports the simultaneous transfer mode such as the EN-DC, a filter circuit that transfers a signal of each band with low loss and low noise figure is disposed. Here, when the two bands corresponding to the signals to be simultaneously transferred are in proximity to each other, the filter circuit is required to have high attenuation characteristics in the band near the passband. An acoustic wave filter is suitable as a filter circuit so as to satisfy this requirement. However, with an acoustic wave filter, an attenuation amount is insufficient in the band distant from the passband. On the other hand, when an LC filter is applied as the filter circuit, the high attenuation characteristics is satisfied in the band distant from the passband, but the attenuation amount is insufficient in the band near the passband. In contrast, in the case of a hybrid filter that includes both an acoustic wave resonator and an inductor and capacitor, it is possible to satisfy the high attenuation characteristics both in the band near the passband and in the band distant from the passband, but it is difficult to satisfy low loss and low noise figure.

In view of the above, the present disclosure is presented to provide a radio frequency circuit and a communication device which satisfy low loss, low noise figure, and high attenuation characteristics over a wide range, and are capable of performing simultaneous transfer.

### Solutions

A radio frequency circuit according to one aspect of the present disclosure includes: a first filter connected to an antenna connection terminal and having a passband including a first band; a second filter connected to the antenna connection terminal and having a passband including a second band; and a first active circuit connected to the first filter. In the radio frequency circuit, the first active circuit includes: a first low noise amplifier; a first capacitor disposed on a feedback path of the first low noise amplifier; and at least one of a first inductor or a first resistor, disposed on the feedback path, and a signal of the first band and a signal of the second band are simultaneously transferable.

### Advantageous Effects

According to the present disclosure, it is possible to provide a radio frequency circuit and a communication device which satisfy low loss, low noise figure, and high attenuation characteristics over a wide range, and are capable of performing simultaneous transfer.

### BRIEF DESCRIPTION OF DRAWINGS

These and other advantages and features will become apparent from the following description thereof taken in conjunction with the accompanying Drawings, by way of non-limiting examples of embodiments disclosed herein.

FIG. 1 is a diagram illustrating a circuit configuration of a radio frequency circuit and a communication device according to Embodiment 1.

FIG. 2A is a diagram illustrating a first example of the circuit configuration of a first active circuit according to Embodiment 1.

FIG. 2B is a diagram illustrating a second example of the circuit configuration of the first active circuit according to Embodiment 1.

FIG. 2C is a diagram illustrating a third example of the circuit configuration of the first active circuit according to Embodiment 1.

FIG. 3 is a diagram illustrating the passing characteristics of a first filter and the first active circuit according to Embodiment 1.

FIG. 4 is a diagram illustrating the passing characteristics of a first filter and a first active circuit according to Variation 1 of Embodiment 1.

FIG. 5 is a diagram illustrating the passing characteristics of a first filter and a first active circuit according to Variation 2 of Embodiment 1.

FIG. 6A is a diagram illustrating the passing characteristics of a first filter and a first active circuit according to Variation 3 of Embodiment 1.

FIG. 6B is a diagram illustrating the passing characteristics of a first filter and a first active circuit according to Variation 4 of Embodiment 1.

FIG. 7 is a diagram illustrating a circuit configuration of a radio frequency circuit according to Embodiment 2.

FIG. 8A is a diagram illustrating a first example of the circuit configuration of a first active circuit according to Embodiment 2.

FIG. 8B is a diagram illustrating a second example of the circuit configuration of the first active circuit according to Embodiment 2.

FIG. 8C is a diagram illustrating a third example of the circuit configuration of the first active circuit according to Embodiment 2.

FIG. 8D is a diagram illustrating a fourth example of the circuit configuration of the first active circuit according to Embodiment 2.

FIG. 8E is a diagram illustrating a fifth example of the circuit configuration of the first active circuit according to Embodiment 2.

FIG. 9A is a diagram illustrating the circuit state of a radio frequency circuit in the first mode according to Variation 5 of Embodiment 2.

FIG. 9B is a diagram illustrating the circuit state of the radio frequency circuit in the third mode according to Variation 5 of Embodiment 2.

FIG. 10 is a diagram illustrating the passing characteristics of a first filter and a first active circuit according to Variation 5 of Embodiment 2.

FIG. 11 is a diagram illustrating a circuit configuration of a radio frequency circuit according to Variation 6 of Embodiment 2.

FIG. 12A is a plan view illustrating the arrangement of a radio frequency circuit according to Embodiment 3.

FIG. 12B is a cross-sectional view illustrating the arrangement of the radio frequency circuit according to Embodiment 3.

FIG. 13 is a diagram illustrating a configuration of a radio frequency circuit according to Embodiment 4.

### DESCRIPTION OF EMBODIMENTS

The following describes in detail embodiments of the present disclosure. It should be noted that the embodiments described below each show a general or specific example. The numerical values, shapes, materials, structural components, the arrangement and connection of the structural components, and so on, illustrated in the following embodiments are mere examples, and therefore do not limit the present disclosure. Among the structural components in the following embodiments, structural components not recited in the independent claims are described as arbitrary structural components. In addition, the sizes of structural components and the ratios of the sizes in the drawings are not necessarily strictly illustrated. In each of the diagrams, substantially the same structural components are denoted by the same reference signs, and redundant description may be omitted or simplified.

In addition, in the following description, terms indicating relationships between components such as parallel and vertical and terms indicating the shapes of components such as a quadrilateral shape, and numerical ranges do not represent only the strict meanings but include also a substantially equivalent range, such as a difference of approximately several percent.

In addition, in the following embodiments, “A and B are connected to each other” is defined not only to mean that A and B are in contact with each other, but also to mean that A and B are electrically connected via a conductive electrode, a conductive terminal, a line, or an other circuit component, etc. In addition, the meaning of “to be connected between A and B” is to be connected to both A and B between A and B.

In each of the diagrams described below, the x-axis and the y-axis are orthogonal to each other on a plane parallel to the principal surface of the module board. In addition, the z-axis is perpendicular to the principal surface of the module board. The positive direction of the z-axis indicates an upward direction and the negative direction of the z-axis indicates a downward direction.

In addition, in the circuit configuration according to the present disclosure, the meaning of “in a plan view” is to view an object by orthographically projecting the object on the xy-plane from the z-axis positive side. The meaning of “a component is disposed on a principal surface of a board” includes not only that the component is disposed on the principal surface in a state in which the component is in contact with the principal surface of the board, but also that the component is disposed above the principal surface of the board without contacting the principal surface, and that a portion of the component is embedded in the board from a principal surface side.

In addition, in the following description, a “transmission path” refers to a transfer path including a line along which a radio frequency transmission signal propagates, an electrode directly connected to the line, a terminal directly connected to the line or the electrode, etc. Furthermore, a “reception path” refers to a transfer path including: a line along which a radio frequency reception signal propagates; an electrode directly connected to the line; a terminal directly connected to the line or the electrode; and the like.

### Embodiment 1

### 1.1 Circuit Configuration of Radio Frequency Circuit 1 and Communication Device 5

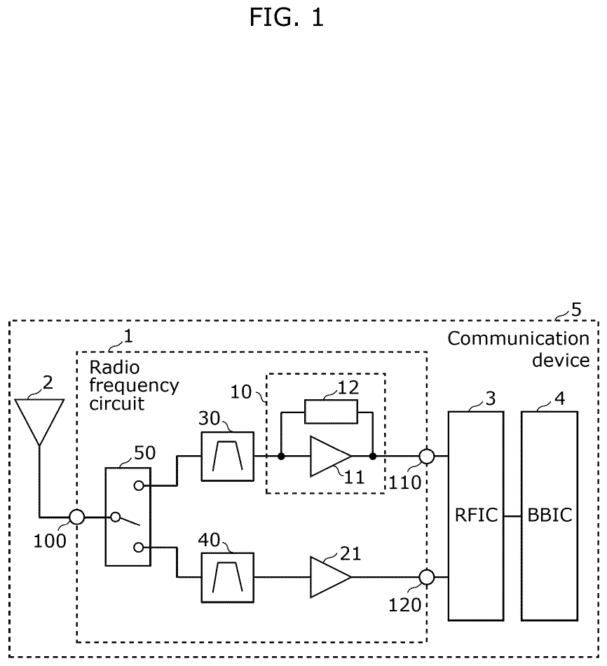

The following describes circuit configurations of radio frequency circuit 1 and communication device 5 according to the present embodiment, with reference to FIG. 1. FIG. 1 is a diagram illustrating the circuit configurations of radio frequency circuit 1 and communication device 5 according to Embodiment 1.

### 1.1.1 Circuit Configuration of Communication Device 5

First, the circuit configuration of communication device 5 will be described. As illustrated in FIG. 1, communication device 5 according to the present embodiment includes radio frequency circuit 1, antenna 2, RF signal processing circuit (RFIC) 3, and baseband signal processing circuit (BBIC) 4.

Radio frequency circuit 1 transfers a radio frequency signal between antenna 2 and RFIC 3. A detailed circuit configuration of radio frequency circuit 1 will be described later.

Antenna 2 is connected to antenna connection terminal 100 of radio frequency circuit 1, transfers a radio frequency signal that has been output from radio frequency circuit 1, or receives a radio frequency signal from the outside and outputs the radio frequency signal to radio frequency circuit 1.

RFIC 3 is one example of a signal processing circuit that processes a radio frequency signal. More specifically, RFIC 3 performs signal processing, by down-conversion or the like, on a radio frequency reception signal input via the reception path of radio frequency circuit 1, and outputs the reception signal generated by the signal processing to BBIC 4. In addition, RFIC 3 performs signal processing, by up-conversion or the like, on a transmission signal input from BBIC 4, and outputs the radio frequency transmission signal generated by the signal processing to the transmission path of radio frequency circuit 1. In addition, RFIC 3 includes a controller that controls a switch, an amplifier, etc. included by radio frequency circuit 1. It should be noted that a portion or the whole of the functions of RFIC 3 as a controller may be located outside RFIC 3, and may be located, for example, in BBIC 4 or radio frequency circuit 1.

BBIC 4 is a baseband signal processing circuit that performs signal processing using an intermediate frequency band including frequencies lower than frequencies of a radio frequency signal that is transferred by radio frequency circuit 1. The signals processed by BBIC 4 include, for example, an image signal for image display and/or a sound signal for telephone conversation via a speaker.

It should be noted that, in communication device 5 according to the present embodiment, antenna 2 and BBIC 4 are not indispensable structural components.

### 1.1.2 Circuit Configuration of Radio Frequency Circuit 1

Next, a circuit configuration of radio frequency circuit 1 will be described. As illustrated in FIG. 1, radio frequency circuit 1 includes active circuit 10, low noise amplifier 21, filters 30 and 40, switch 50, antenna connection terminal 100, and radio frequency output terminals 110 and 120.

Antenna connection terminal 100 is connected to antenna 2. Radio frequency output terminals 110 and 120 are terminals for outputting radio frequency reception signals from radio frequency circuit 1 to RFIC 3.

Filter 30 is one example of a first filter and has a passband including a first band. The input terminal of filter 30 is connected to antenna connection terminal 100 via switch 50.

Filter 40 is one example of a second filter and has a passband including a second band. A signal of the first band and a signal of the second band are simultaneously transferable. Filter 40 is connected to antenna connection terminal 100 via switch 50.

The first band and the second band, as well as a third band described below, are frequency bands predefined by standardization organizations (e.g., 3GPP, Institute of Electrical and Electronics Engineers (IEEE), etc.) for communication systems established using radio access technology (RAT). According to the present embodiment, the LTE system and the 5G-NR system can be used as the communication system, for example. However, the communication system is not limited to these examples.

Active circuit 10 is one example of a first active circuit, and is connected to the output terminal of filter 30. Active circuit 10 includes low noise amplifier 11 and feedback circuit 12.

Low noise amplifier 11 is one example of a first low noise amplifier, and amplifies a radio frequency reception signal (hereinafter referred to as reception signal) of the first band that has been input through antenna connection terminal 100. Low noise amplifier 11 is connected between filter 30 and radio frequency output terminal 110. Low noise amplifier 11 includes an amplification transistor, a power supply circuit for supplying a DC voltage to the amplification transistor, and a bias circuit for supplying a bias voltage or a bias current to the amplification transistor.

It should be noted that the active circuit is defined as a circuit that operates as a result of being supplied with a DC voltage from the power supply circuit.

Feedback circuit 12 is a circuit disposed on a feedback path between the input terminal and the output terminal of low noise amplifier 11, and includes a first capacitor and at least one of a first inductor or a first resistor.

Switch 50 includes two single pole single throw (SPST) switch elements. One of the terminals of each of the switch elements is connected to antenna connection terminal 100. The other of the terminals of the each of the switch elements is connected to filter 30 or 40. With this configuration, switch 50 connects and disconnects antenna connection terminal 100 and filter 30, and connects and disconnects antenna connection terminal 100 and filter 40, based on a control signal from RFIC 3, for example. It should be noted that the total number of switch elements included by switch 50 is set appropriately according to the total number of filters included by radio frequency circuit 1.

Low noise amplifier 21 amplifies a reception signal of the second band that has been input through antenna connection terminal 100. Low noise amplifier 21 is connected between filter 40 and radio frequency output terminal 120.

It should be noted that an impedance matching circuit may be inserted in at least one of a portion between antenna connection terminal 100 and switch 50, a portion between switch 50 and radio frequency output terminal 110, or a portion between switch 50 and radio frequency output terminal 120.

It should be also noted that, among the circuit elements of radio frequency circuit 1 illustrated in FIG. 1, switch 50 and low noise amplifier 21 are not indispensable. In this case, filters 30 and 40 may be directly connected to antenna connection terminal 100.

According to the above-described configuration, radio frequency circuit 1 is capable of performing: a first mode in which a reception signal of the first band and a reception signal of the second band are simultaneously transferred; a second mode in which only a reception signal of the first band is transferred; and a fourth mode in which only a reception signal of the second band is transferred.

In addition, active circuit 10 is enabled to have both an amplification function and a filter function, by including the first capacitor and at least one of the first inductor or the first resistor on the feedback path. Therefore, filter 30 and active circuit 10 are capable of sharing the near attenuation characteristics and distant attenuation characteristics of the first band. In addition, the first capacitor and at least one of the first inductor or the first resistor of active circuit 10 are disposed on the feedback path and not on the main path through which a reception signal of the first band is transferred, and thus it is possible to reduce the transfer loss or noise figure of the reception signal of the first band compared to a circuit in which two filters including filter 30 are disposed on the main path. As a result, it is possible to provide radio frequency circuit 1 and communication device 5 which satisfy low loss, low noise figure, and high attenuation characteristics over a wide range, and are capable of performing simultaneous transfer.

### 1.1.3 Specific Circuit Configuration of Active Circuit 10

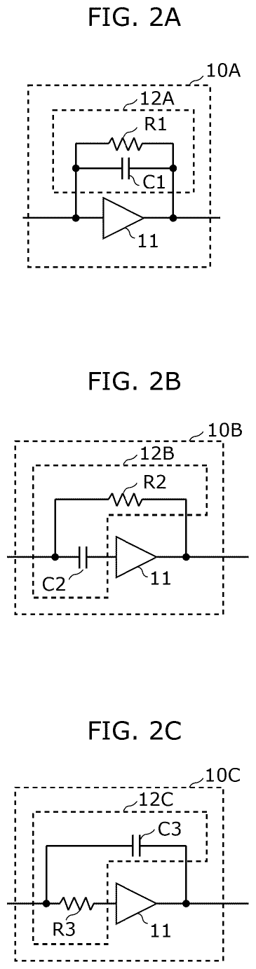

FIG. 2A is a diagram illustrating a first example of the circuit configuration of active circuit 10 according to Embodiment 1. As illustrated in the diagram, active circuit 10A which is the first example of active circuit 10 includes low noise amplifier 11 and feedback circuit 12A.

Feedback circuit 12A includes capacitor C1 and resistor R1. Capacitor C1 is one example of a first capacitor and is connected between the input terminal and the output terminal of low noise amplifier 11. Resistor R1 is one example of a first resistor and is connected between the input terminal and the output terminal of low noise amplifier 11. Capacitor C1 and resistor R1 are connected in parallel.

FIG. 2B is a diagram illustrating a second example of the circuit configuration of active circuit 10 according to Embodiment 1. As illustrated in the diagram, active circuit 10B which is the second example of active circuit 10 includes low noise amplifier 11 and feedback circuit 12B.

Feedback circuit 12B includes capacitor C2 and resistor R2. Capacitor C2 is one example of the first capacitor and is connected to the input terminal of low noise amplifier 11. Resistor R2 is one example of the first resistor and is connected to the output terminal of low noise amplifier 11. Capacitor C2 and resistor R2 are connected in series between the input terminal and the output terminal of low noise amplifier 11.

FIG. 2C is a diagram illustrating a third example of the circuit configuration of active circuit 10 according to Embodiment 1. As illustrated in the diagram, active circuit 10C which is the third example of active circuit 10 includes low noise amplifier 11 and feedback circuit 12C.

Feedback circuit 12C includes capacitor C3 and resistor R3. Capacitor C3 is one example of the first capacitor and is connected to the output terminal of low noise amplifier 11. Resistor R3 is one example of the first resistor and is connected to the input terminal of low noise amplifier 11. Resistor R3 and capacitor C3 are connected in series between the input terminal and the output terminal of low noise amplifier 11.

According to the above-described circuit configuration, each of active circuits 10A, 10B, and 10C is enabled to have both an amplification function and a filter function.

It should be noted that the circuit configuration of active circuit 10 is not limited to active circuits 10A, 10B and 10C. For example, an inductor may be added to each of feedback circuits 12A, 12B and 12C, or an inductor may be provided in place of each of resistors R1, R2 and R3.

### 1.1.4 Passing Characteristics of Active Circuit 10 and Filter 30

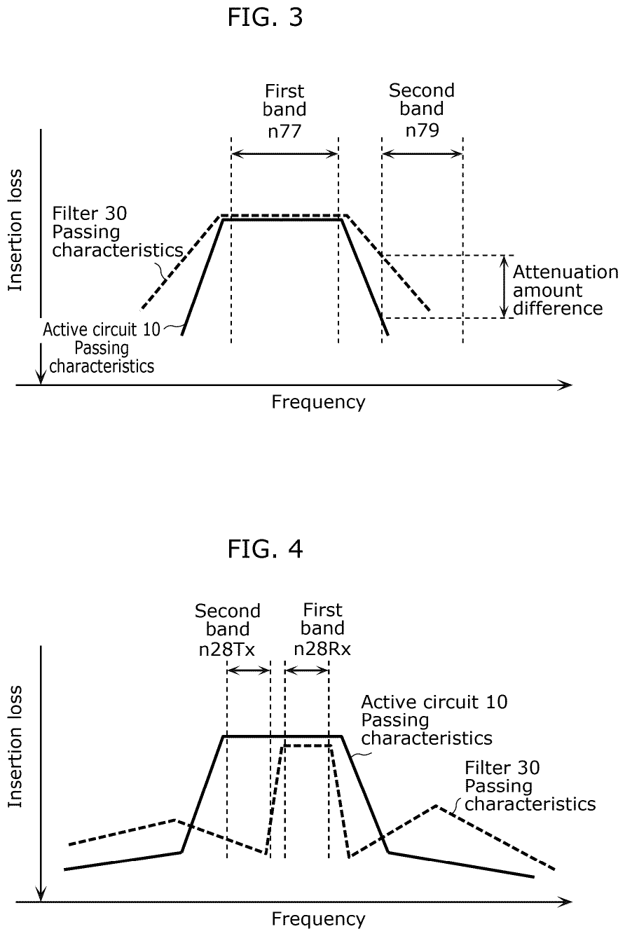

FIG. 3 is a diagram illustrating the passing characteristics of filter 30 and active circuit 10 according to Embodiment 1. It should be noted that the vertical axis in the diagram indicates the insertion loss of filter 30 and the insertion loss excluding the amplification gain of active circuit 10.

The first band is a first time division duplex (TDD) band that is used in TDD, and is, for example, n77 (3300-4200 MHz) for 5G-NR. The second band is a second TDD band that is used in TDD, and is, for example, n79 (4400-5000 MHz) for 5G-NR.

Filter 30 is an LC filter including one or more inductors and one or more capacitors, and has the first band as a passband and the second band as an attenuation band. Active band 10 also has the first band as a passband and the second band as an attenuation band.

Since filter 30 is an LC filter, the attenuation amount of active circuit 10 in the frequency region (4200-4400 MHz) between the first band (n77) and the second band (n79) is larger than the attenuation amount of filter 30 in that frequency region.

According to this configuration, it is possible to implement high attenuation over a wide range, by attenuating the distant attenuation band of the first band (n77) with filter 30 and attenuating the near attenuation band of the first band (n77) with active circuit 10.

It should be noted that, in this specification, the attenuation amount in a given band of a filter is defined as the ratio (dB) of the average value of the insertion loss in the passband of the filter to the average value of the insertion loss in the given band. In addition, the attenuation amount in a given band of an active circuit is defined as the ratio (dB) of the average value of the insertion loss in the passband of the active circuit to the average value of the insertion loss in the given band.

It should be noted that the first band may be either Band 42 (3400-3600 MHz) for 4G-LTE and n78 (3300-3800 MHz) for 5G-NR.

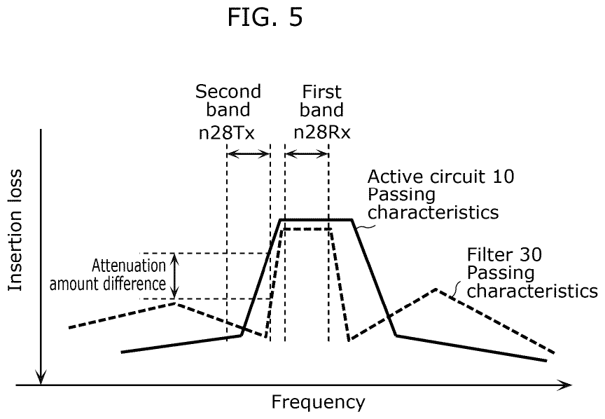

FIG. 4 is a diagram illustrating the passing characteristics of filter 30 and active circuit 10 according to Variation 1 of Embodiment 1. It should be noted that the vertical axis in the diagram indicates the insertion loss of filter 30 and the insertion loss excluding the amplification gain of active circuit 10.

The first band is the downlink operating band of the first frequency division duplexing (FDD) band that is used in FDD, e.g., the reception band of n28 (n28-Rx: 758-803 MHz) for 5G-NR. The second band is the uplink operating band of the second FDD band that is used in FDD, e.g., the transmission band of n28 (n28-Tx: 703-748 MHz) for 5G-NR.

Filter 30 is an acoustic wave filter including one or more acoustic wave resonators, and has the first band as a passband and the second band as an attenuation band. Active band 10 has the first band and the second band as the passband.

Filter 30 is, for example, any one of (1) a surface acoustic wave (SAW) filter, (2) an acoustic wave filter using a bulk acoustic wave (BAW), and (3) a hybrid filter using an acoustic wave resonator, inductor, and capacitor.

According to the above-described configuration, since filter 30 is an acoustic wave filter, it is possible to implement high attenuation over a wide range, by attenuating the near attenuation band of the reception band of the first FDD band with filter 30 and the distant attenuation band of the first FDD band with active circuit 10.

It should be noted that the first FDD band and the second FDD band may be the same communication band or different communication bands.

In addition, the first band may be any one of Band 5 (Tx: 824-849 MHz, Rx: 869-894 MHz), Band 8 (Tx: 880-915 MHz, Rx: 925-960 MHz), Band 12 (Tx: 699-716 MHz, Rx: 729-746 MHz), Band 13 (Tx: 777-787 MHz, Rx: 746-756 MHz), Band 14 (Tx: 788-798 MHz, Rx: 758-768 MHz), Band 17 (Tx: 704-716 MHz, Rx: 734-746 MHz), Band 20 (Tx: 832-862 MHz, Rx: 791-821 MHz), Band 26 (Tx: 814-849 MHz, Rx: 859-894 MHz), Band 28 (Tx: 703-748 MHz, Rx: 758-803 MHz), or Band 71 (Tx: 663-698 MHz, Rx: 617-652 MHz) for 4G-LTE, or may be any one of n5, n8, n12, n13, n14, n17, n20, n26, or n71 for 5G-NR. The second band may be any one of Band 5, Band 8, Band 12, Band 13, Band 14, Band 17, Band 20, Band 26, Band 28, or Band 71 for 4G-LTE, or may be any one of n5, n8, n12, n13, n14, n17, n20, n26, or n71 for 5G-NR.

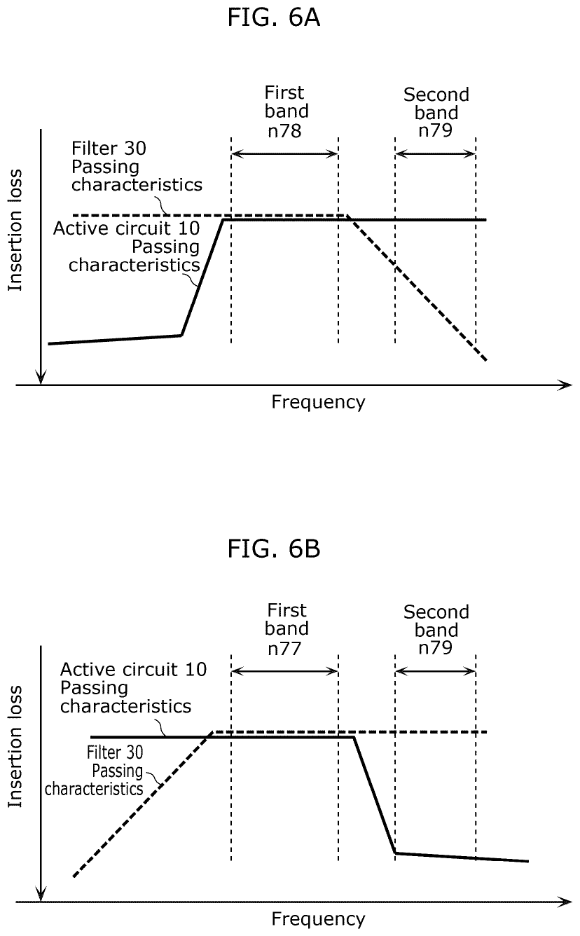

FIG. 5 is a diagram illustrating the passing characteristics of filter 30 and active circuit 10 according to Variation 2 of Embodiment 1. It should be noted that the vertical axis in the diagram indicates the insertion loss of filter 30 and the insertion loss excluding the amplification gain of active circuit 10.

The first band is the downlink operating band of the first FDD band, e.g., the reception band of n28 (n28-Rx) for 5G-NR. The second band is the uplink operating band of the second FDD band, e.g., the transmission band of n28 (n28-Tx) for 5G-NR.

Filter 30 is an acoustic wave filter including one or more acoustic wave resonators, and has the first band as a passband and the second band as an attenuation band. Active band 10 also has the first band as a passband and the second band as an attenuation band.

Since filter 30 is an acoustic wave filter, the attenuation amount of filter 30 at the frequency end closer to the first band (n28-Rx) out of the two frequency ends of the second band (n28-Tx) is larger than the attenuation amount of active circuit 10 at the above-described frequency end.

According to the above-described configuration, it is possible to supplement, with active circuit 10, the near attenuation of the first band (n28-Rx) which is insufficient with filter 30 alone.

It should be noted that the first FDD band and the second FDD band may be the same communication band or different communication bands.

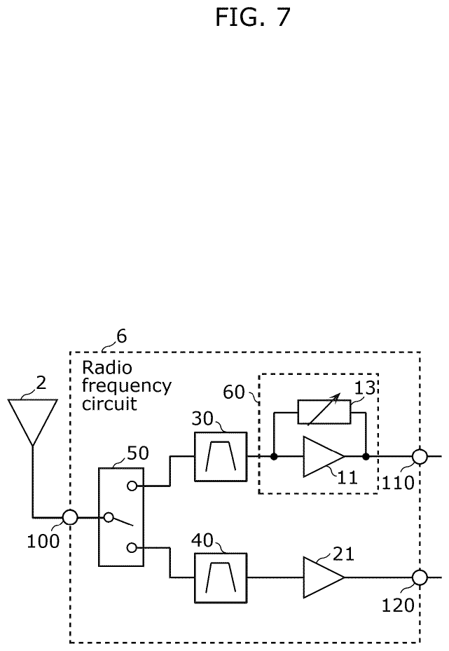

FIG. 6A is a diagram illustrating the passing characteristics of filter 30 and active circuit 10 according to Variation 3 of Embodiment 1. It should be noted that the vertical axis in the diagram indicates the insertion loss of filter 30 and the insertion loss excluding the amplification gain of active circuit 10.

The first band is, for example, n78 for 5G-NR. The second band is, for example, n79 for 5G-NR. The first band is located on the lower-frequency side than the second band.

Filter 30 is a low-pass filter that includes the first band (n78) in the passband and the second band (n79) in the attenuation band.

Active circuit 10 is a high-pass filter that includes the first band (n78) in the passband and the band on the lower-frequency side than the first band in the attenuation band.

According to the above-described configuration, it is possible to implement high attenuation over a wide range, by sharing, between filter 30 and active circuit 10, the attenuation of a lower-frequency-side band and the attenuation of a higher-frequency-side band of the first band (n78).

It should be noted that the first band may be n77 for 5G-NR.

FIG. 6B is a diagram illustrating the passing characteristics of filter 30 and active circuit 10 according to Variation 4 of Embodiment 1. It should be noted that the vertical axis in the diagram indicates the insertion loss of filter 30 and the insertion loss excluding the amplification gain of active circuit 10.

The first band is, for example, n77 for 5G-NR. The second band is, for example, n79 for 5G-NR. The first band is located on the lower-frequency side than the second band.

Active circuit 10 is a low-pass filter that includes the first band (n77) in the passband and the second band (n79) in the attenuation band.

Filter 30 is a high-pass filter that includes the first band (n77) in the passband and the band on the lower-frequency side than the first band in the attenuation band.

According to the above-described configuration, it is possible to implement high attenuation over a wide range, by sharing, between filter 30 and active circuit 10, the attenuation of a lower-frequency-side band and the attenuation of a higher-frequency-side band of the first band (n77).

It should be noted that the first band may be n78 for 5G-NR.

In the present embodiment, when the first band is the first TDD band and the second band is the second TDD band, the first band may be wider than the second band.

### Embodiment 2

In the present embodiment, a radio frequency circuit including an active circuit with variable filter passing characteristics will be described.

### 2.1 Circuit Configuration of Radio Frequency Circuit 6

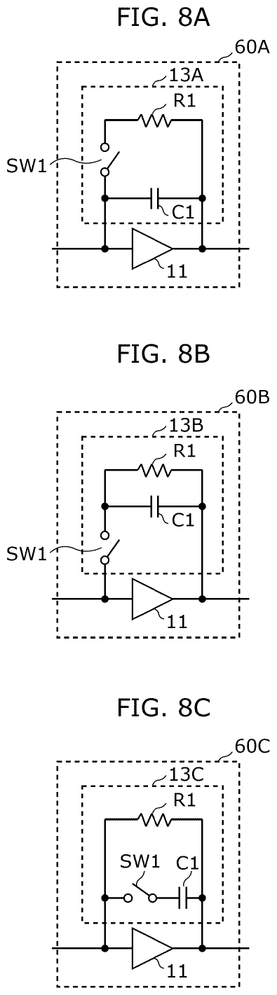

FIG. 7 is a diagram illustrating a circuit configuration of radio frequency circuit 6 according to Embodiment 2. As illustrated in the diagram, radio frequency circuit 6 includes active circuit 60, low noise amplifier 21, filters 30 and 40, switch 50, antenna connection terminal 100, and radio frequency output terminals 110 and 120. Radio frequency circuit 6 according to the present embodiment differs only in the configuration of active circuit 60 compared to radio frequency circuit 1 according to Embodiment 1. In the following, description of the configuration of radio frequency circuit 6 according to the present embodiment that is the same as the configuration of radio frequency circuit 1 according to Embodiment 1 will be omitted, and description will be centered on a different configuration.

Active circuit 60 is one example of the first active circuit and is connected to the output terminal of filter 30. Active circuit 60 includes low noise amplifier 11 and feedback circuit 13.

Low noise amplifier 11 is one example of the first low noise amplifier and amplifies a reception signal of the first band that has been input through antenna connection terminal 100. Low noise amplifier 11 is connected between filter 30 and radio frequency output terminal 110. Low noise amplifier 11 includes an amplification transistor, a power supply circuit for supplying a DC voltage to the amplification transistor, and a bias circuit for supplying a bias voltage or a bias current to the amplification transistor.

Feedback circuit 13 is a circuit disposed on a feedback path between the input terminal and output terminal of low noise amplifier 11, and includes a first capacitor, at least one of a first inductor or a first resistor, and a first switch. The first switch is disposed on the above-described feedback path, and connects and disconnects low noise amplifier 11 and at least one of the first capacitor, the first inductor, or the first resistor.

According to the above-described configuration, active circuit 60 is enabled to have both an amplification function and a filter function, by including the first capacitor and at least one of the first inductor or the first resistor on the feedback path. As a result, filter 30 and active circuit 60 are capable of sharing the near attenuation characteristics and distant attenuation characteristics of the first band. In addition, the first capacitor and at least one of the first inductor or the first resistor of active circuit 60 are disposed on the feedback path and not on the main path through which a reception signal of the first band is transferred, and thus it is possible to reduce the transfer loss or noise figure of the reception signal of the first band compared to a circuit in which two filters including filter 30 are disposed on the main path.

In addition, the filter characteristics of active circuit 60 can be changed by switching of the first switch, and thus it is possible to optimize the transmission loss and noise figure of the signal of the first band.

In addition, radio frequency circuit 6 is capable of performing: a first mode in which a reception signal of the first band and a reception signal of the second band are simultaneously transferred; a second mode in which only a reception signal of the first band is transferred; and a fourth mode in which only a reception signal of the second band is transferred.

Here, the first switch is in the conducting state in the first mode in which a signal of the first band and a signal of the second band are simultaneously transferred, and the first switch is in the non-conducting state in the second mode in which only a signal of the first band is transferred out of the signal of the first band and a signal of the second band.

According to the-above described configuration, it is possible to change the passing characteristics of active circuit 60 between the first mode and the second mode, by switching of the first switch. It is thus possible to optimize the transmission loss, noise figure, and isolation characteristics of the signal of the first band, according to the transfer mode.

### 2.2 Specific Circuit Configuration of Active Circuit 60

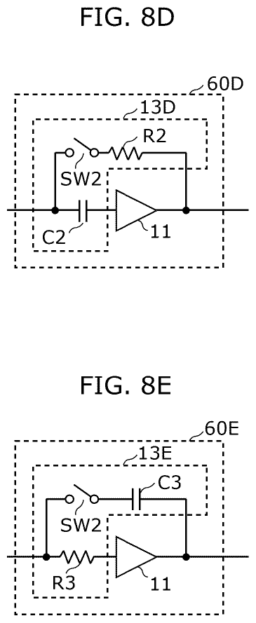

FIG. 8A is a diagram illustrating a first example of the circuit configuration of active circuit 60 according to Embodiment 2. As illustrated in the diagram, active circuit 60A which is the first example of active circuit 60 includes low noise amplifier 11 and feedback circuit 13A.

Feedback circuit 13A includes capacitor C1, resistor R1, and switch SW1. Capacitor C1 is one example of the first capacitor and is connected between the input terminal and output terminal of low noise amplifier 11. Resistor R1 is one example of the first resistor. Switch SW1 is one example of the first switch. Resistor R1 and switch SW1 are directly connected between the input terminal and output terminal of low noise amplifier 11. In other words, the series connection circuit of resistor R1 and switch SW1 is connected in parallel with capacitor C1. Switch SW1 is disposed on the feedback path, and connects and disconnects low noise amplifier 11 and resistor R1.

FIG. 8B is a diagram illustrating a second example of the circuit configuration of active circuit 60 according to Embodiment 2. As illustrated in the diagram, active circuit 60B which is the second example of active circuit 60 includes low noise amplifier 11 and feedback circuit 13B.

Feedback circuit 13B includes capacitor C1, resistor R1, and switch SW1. Capacitor C1 is one example of the first capacitor. Resistor R1 is one example of the first resistor. Switch SW1 is one example of the first switch. Resistor R1 and capacitor C1 are connected in parallel. The parallel connection circuit of resistor R1 and capacitor C1 and switch SW1 are directly connected between the input terminal and output terminal of low noise amplifier 11. Switch SW1 is disposed on the feedback path, and connects and disconnects low noise amplifier 11 and resistor R1 and capacitor C1.

FIG. 8C is a diagram illustrating a third example of the circuit configuration of active circuit 60 according to Embodiment 2. As illustrated in the diagram, active circuit 60C which is the third example of active circuit 60 includes low noise amplifier 11 and feedback circuit 13C.

Feedback circuit 13C includes capacitor C1, resistor R1, and switch SW1. Capacitor C1 is one example of the first capacitor. Resistor R1 is one example of the first resistor. Switch SW1 is one example of the first switch. Switch SW1 and capacitor C1 are connected in series. The series connection circuit of switch SW1 and capacitor C1 and resistor R1 are connected in parallel between the input terminal and the output terminal of low noise amplifier 11. Switch SW1 is disposed on the feedback path, and connects and disconnects low noise amplifier 11 and capacitor C1.

FIG. 8D is a diagram illustrating a fourth example of the circuit configuration of active circuit 60 according to Embodiment 2. As illustrated in the diagram, active circuit 60D which is the fourth example of active circuit 60 includes low noise amplifier 11 and feedback circuit 13D.

Feedback circuit 13D includes capacitor C2, resistor R2, and switch SW2. Capacitor C2 is one example of the first capacitor. Resistor R2 is one example of the first resistor. Switch SW2 is one example of the first switch. Capacitor C2, switch SW2, and resistor R2 are connected in series between the input terminal and output terminal of low noise amplifier 11. Capacitor C2 is disposed in series on the path between the input terminal of low noise amplifier 11 and filter 30. Switch SW2 is disposed on the feedback path, and connects and disconnects low noise amplifier 11 and resistor R2. The above-described configuration allows active circuit 60D to have the amplification function and the high-pass filter function.

FIG. 8E is a diagram illustrating a fifth example of the circuit configuration of active circuit 60 according to Embodiment 2. As illustrated in the diagram, active circuit 60E which is the fifth example of active circuit 60 includes low noise amplifier 11 and feedback circuit 13E.

Feedback circuit 13E includes capacitor C3, resistor R3, and switch SW2. Capacitor C3 is one example of the first capacitor. Resistor R3 is one example of the first resistor. Switch SW2 is one example of the first switch. Resistor R3, switch SW2, and capacitor C3 are connected in series between the input terminal and output terminal of low noise amplifier 11. Resistor R3 is disposed in series on the path between the input terminal of low noise amplifier 11 and filter 30. Switch SW2 is disposed on the feedback path, and connects and disconnects low noise amplifier 11 and capacitor C3. The above-described configuration allows active circuit 60E to have the amplification function and the low-pass filter function.

According to the above-described circuit configuration, each of active circuits 60A to 60E is enabled to have both the amplification function and the filter function, and thus it is possible to change the filter characteristics by switching of the switch.

It should be noted that the circuit configuration of active circuit 60 is not limited to active circuits 60A to 60E. For example, an inductor may be added to each of feedback circuits 13A to 13E, or an inductor may be disposed in place of each of resistors R1, R2, and R3.

### 2.3 Passing Characteristics of Active Circuit 60 and Filter 30

The passing characteristics of radio frequency circuit 6 according to Embodiment 2 will be described with reference to FIG. 3. In the case where active circuits 60A to 60C illustrated respectively in FIG. 8A to FIG. 8C are applied to active circuit 60 according to Embodiment 2, the passing characteristics of active circuit 60 are as indicated by the solid line illustrated in FIG. 3 when switch SW1 is in the conducting state. When switch SW1 is in the non-conducting state, the passing characteristics of active circuit 60 are substantially flat in a predetermined frequency range.

In other words, when switch SW1 is in the conducting state, the passing characteristics of the reception path between antenna connection terminal 100 and radio frequency output terminal 110 are indicated by the solid line and the dashed line that are superposed in FIG. 3. In other words, the insertion loss in the first band is degraded, but the attenuation amount in the second band is larger, compared to the case where switch SW1 is in the non-conducting state.

Therefore, in the first mode in which a signal of the first band and a signal of the second band are transferred simultaneously, switch SW1 is in the conducting state. As a result, the isolation between the signal of the first band and the signal of the second band improves. On the other hand, in the second mode in which only a signal of the first band out of the signal of the first band and a signal of the second band is transferred, switch SW1 is in the non-conducting state. As a result, the insertion loss and noise figure of the signal of the first band are reduced.

Next, the passing characteristics of radio frequency circuit 6 according to Embodiment 2 will be described with reference to FIG. 6B. In the case where active circuit 60E illustrated in FIG. 8E is applied to active circuit 60 according to Embodiment 2, the passing characteristics of active circuit 60 are as indicated by the solid line illustrated in FIG. 6B when switch SW2 is in the conducting state. When switch SW2 is in the non-conducting state, the passing characteristics of active circuit 60 are substantially flat in a predetermined frequency range.

In other words, when switch SW2 is in the conducting state, the passing characteristics of the reception path between antenna connection terminal 100 and radio frequency output terminal 110 are indicated by the solid line and the dashed line that are superposed in FIG. 6B. In other words, the insertion loss in the first band is degraded, but the attenuation amount in the second band is larger, compared to the case where switch SW2 is in the non-conducting state.

Therefore, in the first mode in which a signal of the first band and a signal of the second band are transferred simultaneously, switch SW2 is in the conducting state. As a result, the isolation between the signal of the first band and the signal of the second band is improved. On the other hand, in the second mode in which only a signal of the first band out of the signal of the first band and a signal of the second band is transferred, switch SW2 is in the non-conducting state. As a result, the insertion loss and noise figure of the signal of the first band are reduced.

### 2.4 Circuit Configuration of Radio Frequency Circuit 7 According to Variation 5

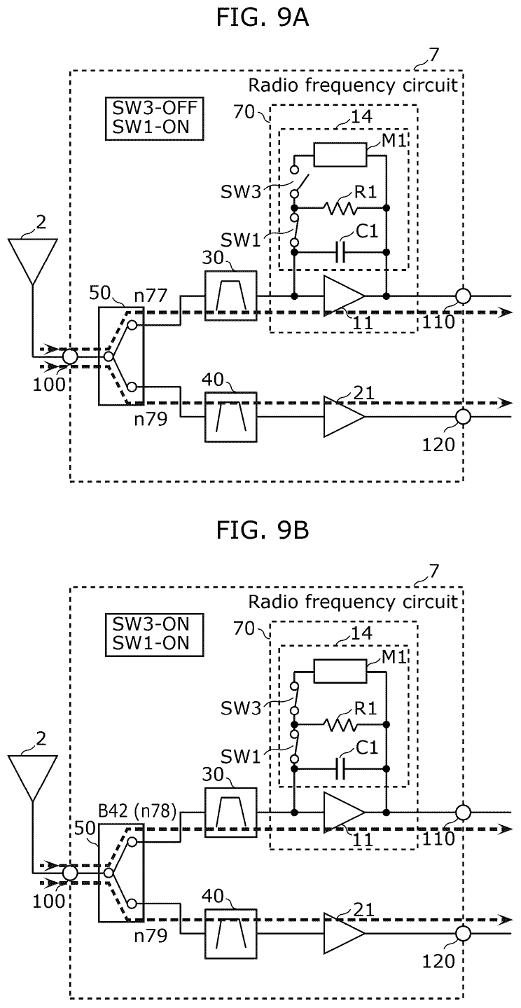

FIG. 9A is a diagram illustrating the circuit state of radio frequency circuit 7 in the first mode according to Variation 5 of Embodiment 2. FIG. 9B is a diagram illustrating the circuit state of radio frequency circuit 7 in the third mode according to Variation 5 of Embodiment 2. As illustrated in FIG. 9A and FIG. 9B, radio frequency circuit 7 includes active circuit 70, low noise amplifier 21, filters 30 and 40, switch 50, antenna connection terminal 100, and radio frequency output terminals 110 and 120. Radio frequency circuit 7 according to the present variation differs only in the configuration of active circuit 70 compared to radio frequency circuit 6 according to Embodiment 2. In the following, description of the configuration of radio frequency circuit 7 according to the present variation that is the same as the configuration of radio frequency circuit 6 according to Embodiment 2 will be omitted, and description will be centered on a different configuration.

Active circuit 70 is one example of the first active circuit and is connected to the output terminal of filter 30. Active circuit 70 includes low noise amplifier 11 and feedback circuit 14.

Feedback circuit 14 is a circuit disposed on the feedback path between the input terminal and the output terminal of low noise amplifier 11, and includes capacitor C1, resistor R1, circuit element M1, and switches SW1 and SW3.

Capacitor C1 is one example of the first capacitor and is connected between the input terminal and the output terminal of low noise amplifier 11. Resistor R1 is one example of the first resistor. Switch SW1 is one example of the first switch. Resistor R1 and switch SW1 are directly connected between the input terminal and output terminal of low noise amplifier 11. In other words, the series connection circuit of resistor R1 and switch SW1 is connected in parallel with capacitor C1. Switch SW1 is disposed on the feedback path, and connects and disconnects low noise amplifier 11 and resistor R1.

Circuit element M1 is at least one of a second capacitor or a second inductor. Switch SW3 is one example of the second switch. The series connection circuit of circuit element M1 and switch SW3 is connected in parallel with resistor R1. Switch SW3 connects and disconnects low noise amplifier 11 and circuit element M1.

It should be noted that the circuit configuration of active circuit 70 is not limited to the above-described circuit configuration. For example, the connection configuration of capacitor C1, resistor R1, and switch SW1 may be the connection configuration of capacitor C1 (or C2, C3), resistor R1 (or R2, R3), and switch SW1 (or SW2) illustrated in FIG. 8A to FIG. 8E. In addition, an inductor may be added to feedback circuit 14, or an inductor may be disposed in place of resistor R1. Furthermore, circuit element M1 and switch SW3 may be disposed on the feedback path between the input terminal and output terminal of low noise amplifier 11.

According to the above-described configuration, radio frequency circuit 7 is capable of changing the filter characteristics of active circuit 70 more p by switching of switches SW1 and SW3, and thus it is possible to optimize the transmission loss and noise figure of the signal of the first band.

### 2.5 Passing Characteristics of Active Circuit 70 and Filter 30

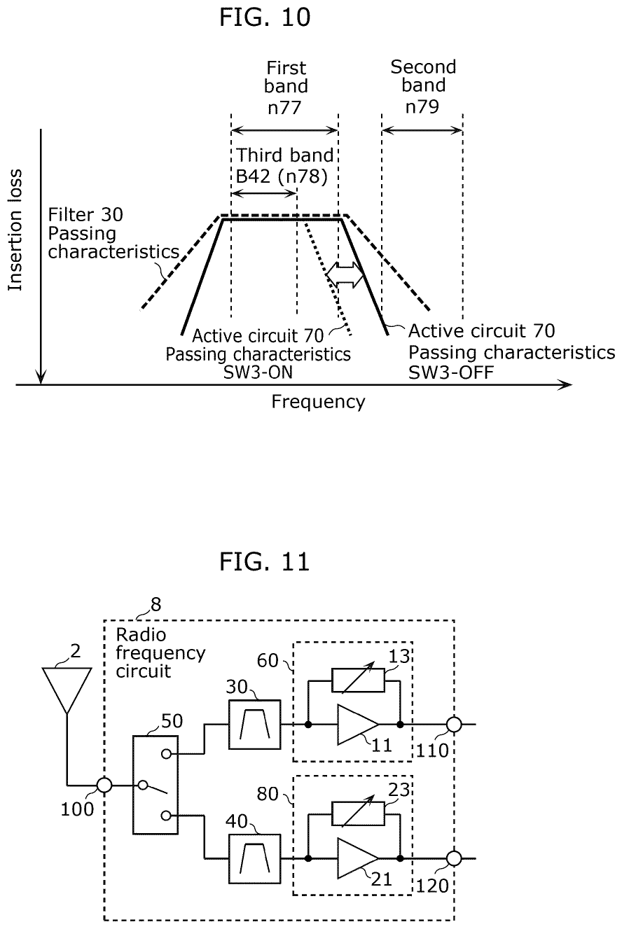

FIG. 10 is a diagram illustrating the passing characteristics of filter 30 and active circuit 70 according to Variation 5 of Embodiment 2.

When switch SW3 is in the conducting state (and switch SW1 is in the conducting state), the passing characteristics of active circuit 70 are as indicated by the thin dashed line illustrated in FIG. 10. When switch SW3 is in the non-conducting state (and switch SW1 is in the conducting state), the passing characteristics of active circuit 70 are as indicated by the solid line illustrated in FIG. 10. Meanwhile, the passing characteristics of filter 30, for example, are as indicated by the coarse dashed line illustrated in FIG. 10.

In other words, when switch SW3 is in the conducting state, the passband of active circuit 70 becomes narrower (i.e., the higher-frequency-side end portion of the passband shifts to the lower-frequency side) compared to when switch SW3 is in the non-conducting state.

In other words, when switch SW3 is in the conducting state, the passband becomes narrower compared to when switch SW3 is in the non-conducting state, which results in an increase in the attenuation amount in the second band.

In radio frequency circuit 7 according to the present variation, the passband of active circuit 70 when switch SW3 is in the non-conducting state (and switch SW1 is in the conducting state) includes the first band, and the passband of active circuit 70 when switch SW3 is in the conducting state (and switch SW1 is in the conducting state) includes the third band. Here, the third band overlaps at least partially the first band.

The first band is n77 for 5G-NR, for example, the second band is n79 for 5G-NR, for example, and the third band is either Band 42 for 4G-LTE or n78 for 5G-NR, for example.

According to the above-described configuration, as indicated in FIG. 9A, in the first mode in which a signal of the first band (n77) and a signal of the second band (n79) are transferred simultaneously, switch SW1 is in the conducting state and switch SW3 is in the non-conducting state. On the other hand, as indicated in FIG. 9B, in the third mode in which a signal of the third band (B42 (n78)) and a signal of the second band (n79) are transferred simultaneously, switch SW1 and switch SW3 are in the conducting state. As a result, the isolation between the reception signal of the third band and the reception signal of the second band are further improved.

According to the-above described configuration, it is possible to change the passing characteristics of active circuit 70 between the first mode and the third mode, by switching of switch SW3. It is thus possible to optimize the transmission loss, noise figure, and isolation characteristics of the signals of the first band and the third band, according to the transfer mode.

### 2.6 Circuit Configuration of Radio Frequency Circuit 8 According to Variation 6

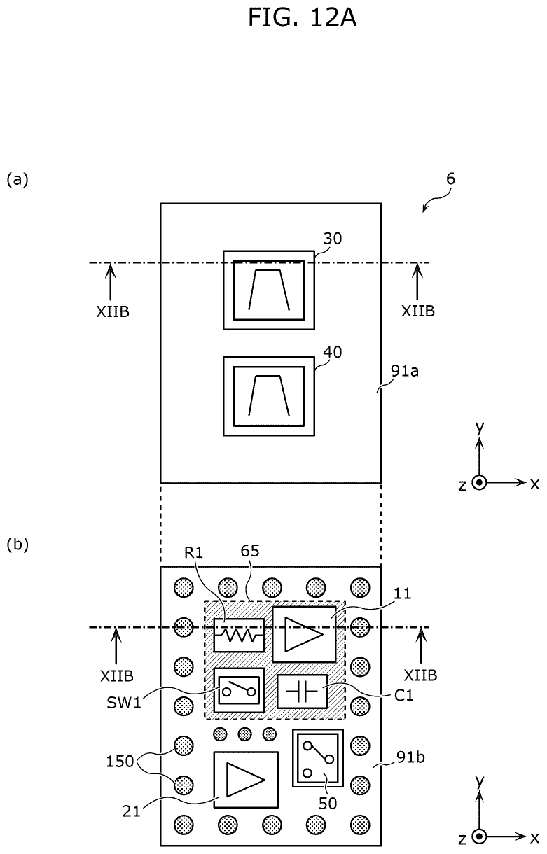

FIG. 11 is a diagram illustrating a circuit configuration of radio frequency circuit 8 according to Variation 6 of Embodiment 2. As illustrated in the diagram, radio frequency circuit 8 includes active circuits 60 and 80, filters 30 and 40, switch 50, antenna connection terminal 100, and radio frequency output terminals 110 and 120. Radio frequency circuit 8 according to the present variation differs only in the configuration of active circuit 80 compared to radio frequency circuit 6 according to Embodiment 2. In the following, description of the configuration of radio frequency circuit 8 according to the present variation that is the same as the configuration of radio frequency circuit 6 according to Embodiment 2 will be omitted, and description will be centered on a different configuration.

Active circuit 80 is one example of a second active circuit and is connected to the output terminal of filter 40. Active circuit 80 includes low noise amplifier 21 and feedback circuit 23.

Low noise amplifier 21 is one example of a second low noise amplifier and amplifies a reception signal of the second band that has been input through antenna connection terminal 100. Low noise amplifier 21 is connected between filter 40 and radio frequency output terminal 120. Low noise amplifier 21 includes an amplification transistor, a power supply circuit for supplying a DC voltage to the amplification transistor, and a bias circuit for supplying a bias current to the amplification transistor.

Feedback circuit 23 is a circuit disposed on a feedback path between the input terminal and output terminal of low noise amplifier 21, and includes a third capacitor, at least one of a third inductor or a third resistor, and a third switch. The third switch is disposed on the above-described feedback path, and connects and disconnects low noise amplifier 21 and at least one of the third capacitor, the third inductor, or the third resistor.

It should be noted that feedback circuit 23 need not necessarily include the third switch.

According to the above-described configuration, active circuit 80 has both an amplification function and a filter function, by including the third capacitor and at least one of the third inductor or the third resistor on the feedback path. As a result, filter 40 and active circuit 80 are capable of sharing the near attenuation characteristics and the distant attenuation characteristics of the second band. In addition, the third capacitor and at least one of the third inductor or the third resistor of active circuit 80 are not disposed on the main path through which a radio frequency signal of the second band is transferred, and thus it is possible to reduce the transfer loss or noise figure of the radio frequency signal of the second band compared to a circuit in which two filters including filter 40 are disposed on the main path.

It should be noted that, in the present embodiment, when the first band is the first TDD band and the second band is the second TDD band, the first band may be wider than the second band.

In addition, the first band may be n46 (5150-5925 MHz) for 5G-NR and the second band may be any one of n79, n96 (5925-6425 MHz), or n97 (5925-7125 MHz) for 5G-NR.

In addition, the first band may be n96 and n97 for 5G-NR, and the second band may be n46 for 5G-NR.

### Embodiment 3

In the present embodiment, the mount configuration of the circuit components included in the radio frequency circuit according to Embodiments 1 and 2 will be described.

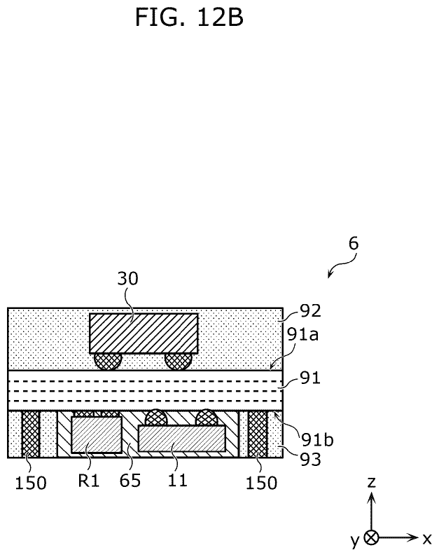

FIG. 12A is a plan view illustrating the arrangement of radio frequency circuit 6. FIG. 12B is a cross-sectional view illustrating the arrangement of radio frequency circuit 6, specifically, a cross-sectional view taken along line XIIB-XIIB of FIG. 12A. It should be noted that (a) in FIG. 12A illustrates the arrangement of the circuit components when, of principal surfaces 91a and 91b located on opposite sides of module board 91, principal surface 91a is viewed from the z-axis positive side. Meanwhile, (b) in FIG. 12A illustrates a perspective view of the arrangement of the circuit components when principal surface 91b is viewed from the z-axis positive side. It should be noted that, although each of the circuit components illustrated in FIG. 12A is attached with a symbol indicating the function of the circuit component such that the arrangement relation of the circuit components is readily understood, such a symbol is not actually attached to radio frequency circuit 6.

Radio frequency circuit 6 illustrated in FIG. 12A and FIG. 12B shows a specific arrangement configuration of each of the circuit components included in radio frequency circuit 6 according to Embodiment 2.

As illustrated in FIG. 12A and FIG. 12B, radio frequency circuit 6 further includes module board 91, resin components 92 and 93, and external-connection terminals 150 in addition to the circuit configuration illustrated in FIG. 7.

Module board 91 is a board which includes principal surface 91a (a first principal surface) and principal surface 91b (a second principal surface) on opposite sides thereof, and on which the circuit components included in radio frequency circuit 6 are mounted. As module board 91, for example, a low temperature co-fired ceramic (LTCC) board having a stacked structure including a plurality of dielectric layers, a high temperature co-fired ceramic (HTCC) board, a component built-in board, a board including a redistribution layer (RDL), or a printed board or the like is used.

Although not illustrated in the diagram, antenna connection terminal 100 and radio frequency output terminals 110 and 120 may be disposed on principal surface 91b.

Resin component 92 is disposed on principal surface 91a, and covers a portion of the circuit components included in radio frequency circuit 6 and principal surface 91a. Resin component 93 is disposed on principal surface 91b, and covers a portion of the circuit components included in radio frequency circuit 6 and principal surface 91b. Resin components 92 and 93 have the function of ensuring the reliability, such as mechanical strength and moisture resistance, of the circuit components included in radio frequency circuit 6. It should be noted that resin components 92 and 93 are not indispensable structural components for radio frequency circuit 6 according to the present embodiment.

As illustrated in FIG. 12A and FIG. 12B, filters 30 and 40 are disposed on principal surface 91a in radio frequency circuit 6. Meanwhile, low noise amplifier 21, switch 50, and low noise amplifier 11, capacitor C1, resistor R1, and switch SW1 which are included in active circuit 60 are disposed on principal surface 91b.

According to the-above described configuration, the circuit components included in radio frequency circuit included 6 are disposed separately on both sides of module board 91, and thus it is possible to reduce the size of radio frequency circuit 6.

Although not illustrated in FIG. 12A, the line that connects the circuit components illustrated in FIG. 7 is provided inside module board 91 and on principal surfaces 91a and 91b In addition, the above-described line may be a bonding wire having ends bonded to principal surfaces 91a and 91b, or any of the circuit components included in radio frequency circuit 6, or may be a terminal, an electrode, or a line disposed on the surface of the circuit components included in radio frequency circuit 6.

In radio frequency circuit 6 according to the present embodiment, a plurality of external-connection terminals 150 are disposed on principal surface 91b. Radio frequency circuit 6 exchanges electrical signals with a motherboard disposed on the z-axis negative side of radio frequency circuit 6 via the plurality of external-connection terminals 150. In addition, one or more of the plurality of external-connection terminals 150 are set to ground potential of the motherboard. Of principal surfaces 91a and 91b, circuit components which are difficult to reduce the height are not disposed on principal surface 91b facing the motherboard, but low noise amplifiers 11 and 21, switches 50 and SW1, capacitor C1, and resistor R1 which are easy to reduce the height are disposed on principal surface 91b.

Here, low noise amplifier 11, capacitor C1, resistor R1, and switch SW1 are provided as a single chip. According to this configuration, it is possible to reduce the size of active circuit 60 and radio frequency circuit 6. It should be noted that the meaning of a plurality of circuit components being provided as a single chip is defined as providing the plurality of circuit components on a single substrate or in a single package.

In addition, according to the present embodiment, low noise amplifier 11, capacitor C1, resistor R1, and switch SW1 are included in a single semiconductor integrated circuit (IC) 65. It should be noted that capacitor C1 and resistor R1 may be, for example, integrated passive devices (IPDs) that are mounted inside or on the surface of a semiconductor substrate in an integrated manner. According to this configuration, it is possible to reduce the heights of capacitor C1 and resistor R1.

Semiconductor IC 65 is configured by, for example, a complementary metal oxide semiconductor (CMOS). More specifically, the semiconductor IC is fabricated by silicon on insulator (SOI) processing. With this, it is possible to manufacture semiconductor IC 65 at low manufacturing cost. It should be noted that semiconductor IC 65 may include at least one of GaAs, SiGe, or GaN. With this, it is possible to output a radio frequency signal having a high-quality amplification performance and noise characteristics.

It should be noted that external-connection terminals 150 may be columnar electrodes that penetrate through resin component 93 in the z-axis direction as illustrated in FIG. 12A and FIG. FIG. 12B, or bump electrodes formed on principal surface 91b. In this case, resin component 93 need not be provided on principal surface 91b.

In addition, in radio frequency circuit 6 according to the present embodiment, each of the circuit components included in radio frequency circuit 6 is disposed on both sides of module board 91, but each of the circuit components may be disposed only on the first principal surface or the second principal surface of the module board. In other words, each of the circuit components included in radio frequency circuit 6 may be mounted on the module board on one side or on both sides thereof.

### Embodiment 4

According to the present embodiment, radio frequency circuit 9 provided in RFIC 3A will be described.

### 4.1 Configuration of Radio Frequency Circuit 9 and Communication Device 5A

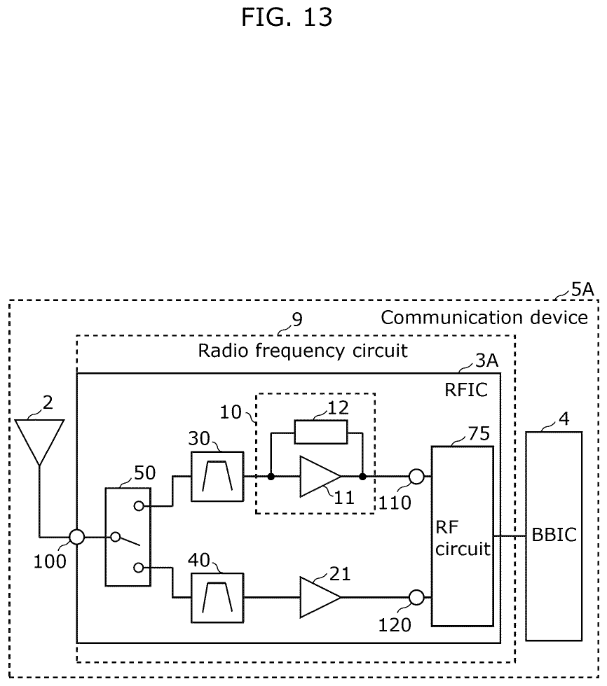

The following describes circuit configurations of radio frequency circuit 9 and communication device 5A according to the present embodiment, with reference to FIG. 13.

FIG. 13 is a diagram illustrating the configuration of radio frequency circuit 9 and communication device 5A according to Embodiment 4. As illustrated in the diagram, communication device 5A includes radio frequency circuit 9, antenna 2, and BBIC 4. Communication device 5A according to the present embodiment is different from communication device 5 according to Embodiment 1 in that RFIC 3A includes radio frequency circuit 9. The following describes communication device 5A according to the present embodiment with a focus on the configuration of radio frequency circuit 9.

Radio frequency circuit 9 transfers a radio frequency signal between antenna 2 and BBIC 4. As illustrated in FIG. 13, radio frequency circuit 9 includes active circuit 10, low noise amplifier 21, filters 30 and 40, switch 50, antenna connection terminal 100, radio frequency output terminals 110, and 120, and RF circuit 75. Radio frequency circuit 9 according to the present embodiment is different from radio frequency circuit 1 according to Embodiment 1 in that radio frequency circuit 9 includes RF circuit 75 and is included in RFIC 3A. In the following, description of the configuration of radio frequency circuit 9 according to the present embodiment that is the same as the configuration of radio frequency circuit 1 according to Embodiment 1 will be omitted, and description will be centered on a different configuration.

RF circuit 75 is one example of a signal processing circuit that processes a radio frequency signal. More specifically, RFIC circuit 75 performs signal processing, by down-conversion or the like, on a radio frequency reception signal input via the reception path of radio frequency circuit 9, and outputs the reception signal generated by the signal processing to BBIC 4. In addition, RF circuit 75 performs signal processing, by up-conversion or the like, on a transmission signal input from BBIC 4, and outputs the radio frequency transmission signal generated by the signal processing to the transmission path of radio frequency circuit 9. In addition, RF circuit 75 includes a controller that controls a switch, an amplifier, etc. included by radio frequency circuit 9. It should be noted that a portion or the whole of the functions of RF circuit 75 as a controller may be located outside RF circuit 75, and may be located, for example, in BBIC 4 or radio frequency circuit 9.

The circuit components included in radio frequency circuit 9 are included in RFIC 3A. More specifically, active circuit 10, low noise amplifier 21, filters 30 and 40, switch 50, antenna connection terminal 100, radio frequency output terminals 110 and 120, and RF circuit 75 are disposed in RFIC 3A.

RFIC 3A is one example of a semiconductor IC, and includes, for example, a CMOS. More specifically, the semiconductor IC is fabricated by SOI processing. With this configuration, it is possible to manufacture RFIC 3A at a low manufacturing cost. It should be noted that RFIC 3A may include at least one of GaAs, SiGe, or GaN. With this, it is possible to output a radio frequency signal having a high-quality amplification performance and noise characteristics.

With the above-described configuration, it is possible to provide radio frequency circuit 9 and communication device 5A which satisfy low loss, low noise figure, and high attenuation characteristics over a wide range, have small sizes, and are capable of performing simultaneous transfer.

It should be noted that radio frequency circuit 9 may not include RF circuit 75, and active circuit 10, low noise amplifier 21, filters 30 and 40, switch 50, antenna connection terminal 100, and radio frequency output terminals 110 and 120 may be included in a single semiconductor IC.

### Advantageous Effects, Etc.

As described above, radio frequency circuit 1 according to Embodiment 1 includes: filter 30 connected to antenna connection terminal 100 and having a passband including a first band; filter 40 connected to antenna connection terminal 100 and having a passband including a second band; and active circuit 10 connected to filter 30. In radio frequency circuit 1, active circuit 10 includes: low noise amplifier 11; a first capacitor disposed on a feedback path of low noise amplifier 11; and at least one of a first inductor or a first resistor, disposed on the feedback path, and a signal of the first band and a signal of the second band are simultaneously transferable.

According to the above-described configuration, active circuit 10 is enabled to have both an amplification function and a filter function, by including the first capacitor and at least one of the first inductor or the first resistor on the feedback path. Therefore, filter 30 and active circuit 10 are capable of sharing the near attenuation characteristics and distant attenuation characteristics of the first band. In addition, the first capacitor and at least one of the first inductor or the first resistor of active circuit 10 are disposed on the feedback path and not on the main path through which a reception signal of the first band is transferred, and thus it is possible to reduce the transfer loss or noise figure of the reception signal of the first band compared to a circuit in which two filters including filter 30 are disposed on the main path. As a result, it is possible to provide radio frequency circuit 1 which satisfies low loss, low noise figure, and high attenuation characteristics over a wide range, and is capable of performing simultaneous transfer.

In addition, in radio frequency circuit 1, the first band may be a first time division duplex (TDD) band, the second band may be a second TDD band, filter 30 may be an LC filter including at least one inductor and at least one capacitor, and an attenuation amount of active circuit 10 in a frequency region between the first band and the second band may be larger than an attenuation amount of filter 30 in the above-described frequency region.

According to the-above described configuration, it is possible to implement high attenuation over a wide range, by attenuating the distant attenuation band of the first band with filter 30 and attenuating the near attenuation band of the first band with active circuit 10.

In addition, in radio frequency circuit 1, the first band may be a downlink operating band of a first frequency division duplexing (FDD) band, the second band may be an uplink operating band of a second FDD band, filter 30 may be an acoustic wave filter including at least one acoustic wave resonator, and active circuit 10 may have a passband including the above-described downlink operating band.

According to the-above described configuration, since filter 30 is an acoustic wave filter, it is possible to implement high attenuation over a wide range, by attenuating the near attenuation band of the reception band of the first FDD band with filter 30 and the distant attenuation band of the first FDD band with active circuit 10.

In addition, in radio frequency circuit 1, active circuit 10 may have an attenuation band including the above-described uplink operating band, and an attenuation amount of filter 30 at a frequency end closer to the first band out of two frequency ends of the second band may be larger than the attenuation amount of active circuit 10 at the above-described frequency end.

According to the above-described configuration, it is possible to supplement, with active circuit 10, the near attenuation of the first band which is insufficient with filter 30 alone.

In addition, in radio frequency circuit 1, the first band may be on a lower-frequency side than the second band, one of filter 30 or active circuit 10 may be a low-pass filter that includes the first band in a passband and the second band in an attenuation band, and an other of filter 30 or active circuit 10 may be a high-pass filter that includes the first band in a passband and a band on a lower-frequency side than the first band in an attenuation band.

According to the above-described configuration, it is possible to implement high attenuation over a wide range, by sharing the attenuation of a lower-frequency-side band and the attenuation of a higher-frequency-side band of the first band between filter 30 and active circuit 10.

In addition, in radio frequency circuit 6 according to Embodiment 2, active circuit 60 may further include a first switch disposed on the feedback path between the first low noise amplifier and at least one of the first capacitor, the first inductor, or the first resistor.

According to the-above described configuration, the filter characteristics of active circuit 60 can be changed by switching of the first switch, and thus it is possible to optimize the transmission loss and noise figure of the signal of the first band.

In addition, in radio frequency circuit 6, in a first mode in which a signal of the first band and a signal of the second band are simultaneously transferred, the first switch may be in a conducting state, and in a second mode in which only a signal of the first band out of the signal of the first band and a signal of the second band is transferred, the first switch may be in a non-conducting state.

According to the-above described configuration, it is possible to change the passing characteristics of active circuit 60 between the first mode and the second mode, by switching of the first switch. As a result, it is possible to optimize the transmission loss, noise figure, and isolation characteristics of the signal of the first band, according to the transfer mode.

In addition, in radio frequency circuit 7 according to Variation 5 of Embodiment 2, active circuit 70 may further include: at least one of a second capacitor or a second inductor, disposed on the feedback path; and switch SW3 that is disposed on the feedback path between low noise amplifier 11 and at least one of the second capacitor or the second inductor.

According to the above-described configuration, radio frequency circuit 7 is capable of changing the filter characteristics of active circuit 70 in more detail by switching of switches SW1 and SW3, and thus it is possible to optimize the transmission loss and noise figure of the signal of the first band.

In addition, in radio frequency circuit 7, a passband of filter 30 and a passband of active circuit 70 may include a third band that overlaps at least partially the first band, in a first mode in which a signal of the first band and a signal of the second band are transferred simultaneously, the first switch SW1 may be in a conducting state and switch SW3 may be in a non-conducting state, and in a third mode in which a signal of the third band and a signal of the second band are transferred simultaneously, switch SW1 and switch SW3 may be in the conducting state.

According to the-above described configuration, it is possible to change the passing characteristics of active circuit 70 between the first mode and the third mode, by switching of switch SW3. As a result, it is possible to optimize the transmission loss, noise figure, and isolation characteristics of the signals of the first band and the third band, according to the transfer mode.

In addition, radio frequency circuit 8 according to Variation 6 of Embodiment 2 may further include active circuit 80 connected to filter 40. In radio frequency circuit 8, active circuit 80 may include: low noise amplifier 21; a third capacitor disposed on a feedback path of low noise amplifier 21; and at least one of a third inductor or a third resistor, disposed on the feedback path.

According to the-above described configuration, filter 40 and active circuit 80 are capable of sharing the near attenuation characteristics and the distant attenuation characteristics of the second band. In addition, it is possible to reduce the transfer loss or noise figure of a radio frequency signal of the second band compared to a circuit in which two filters including filter 40 are disposed on the main path through which a radio frequency signal of the second band is transferred.

In addition, in radio frequency circuit 6 according to Embodiment 3, ow noise amplifier 11, the first capacitor, and the at least one of the first inductor or the first resistor may be disposed on a single board or in a single package.

According to the-above described configuration, it is possible to reduce the size of active circuit 60 and radio frequency circuit 6.

In addition, in radio frequency circuit 6, low noise amplifier 11, the first capacitor, the at least one of the first inductor or the first resistor, and the first switch may be included in a single semiconductor integrated circuit (IC) 65.

According to the-above described configuration, it is possible to reduce the height of active circuit 60 and radio frequency circuit 6.

In addition, radio frequency circuit 6 may further include module board 91 including principal surface 91a and principal surface 91b on opposite sides of module board 91. In radio frequency circuit 6, filter 30 and filter 40 may be disposed on principal surface 91a, and active circuit 60 may be disposed on principal surface 91b.

According to the-above described configuration, it is possible to reduce the size of active radio frequency circuit 6.

In addition, in radio frequency circuit 1, the first band may be any one of Band 42 for 4th generation (4G)-long term evolution (LTE), n77 for 5th generation (5G)-new radio (NR), or n78 for 5G-NR, and the second band may be n79 for 5G-NR.

In addition, in radio frequency circuit 1, the first band and the second band each may be any one of Band 5, Band 8, Band 12, Band 13, Band 14, Band 17, Band 20, Band 26, Band 28, Band 71, n5, n8, n12, n13, n14, n17, n20, n26, n28, or n71. Band 5, Band 8, Band 12, Band 13, Band 14, Band 17, Band 20, Band 26, Band 28, and Band 71 are for 4G-LTE, and n5, n8, n12, n13, n14, n17, n20, n26, n28, and n71 are for 5G-NR.

In addition, in radio frequency circuit 6, the first band may be any one of n77 or n78 for 5G-NR, and the second band may be n79 for 5G-NR.

In addition, in radio frequency circuit 7, the first band may be n77 for 5G-NR, the second band may be n79 for 5G-NR, and the third band may be any one of Band 42 for 4G-LTE or n78 for 5G-NR.

In addition, communication device 5 includes: RFIC 3 configured to process a radio frequency signal; and radio frequency circuit 1 configured to transfer the radio frequency signal between RFIC 3 and antenna 2.

According to the-above described configuration, it is possible to provide communication device 5 which satisfies low loss, low noise figure, and high attenuation characteristics over a wide range, and is capable of performing simultaneous transfer.

### OTHER EMBODIMENTS

Although the radio frequency circuit and the communication device according to the present disclosure have been described above based on Embodiments 1 to 3, the radio frequency circuit and the communication device according to the present disclosure are not limited to the foregoing embodiments. The present disclosure also encompasses other embodiments achieved by combining arbitrary structural components in the above-described embodiments, variations resulting from various modifications to the above-described embodiments that may be conceived by those skilled in the art without departing from the essence of the present disclosure, and various devices that include the above-described radio frequency circuit and communication device.

For example, in the circuit configuration of the radio frequency circuit and the communication device according to the above-described embodiments, another circuit element and line, for example, may be inserted in the path connecting circuit elements and the signal path which are illustrated in the drawings.

In addition, although bands for 5G-NR or 4G-LTE were used in the above-described embodiments, communication bands for other radio access technologies may be used in addition to or instead of these bands. For example, a communication band for the wireless local area network and a millimeter wave band of 7 gigahertz or more may be used. When the millimeter wave band is used, radio frequency circuit 1, antenna 2, and RFIC 3 are included in a millimeter wave antenna module, and a distributed constant filter, for example, may be used as a filter. Although only some exemplary embodiments of the present disclosure have been described in detail above, those skilled in the art will readily appreciate that many modifications are possible in the exemplary embodiments without materially departing from the novel teachings and advantages of the present disclosure. Accordingly, all such modifications are intended to be included within the scope of the present disclosure.

### INDUSTRIAL APPLICABILITY

The present disclosure is applicable widely to communication apparatuses such as mobile phones as a radio frequency circuit disposed in a front-end unit.

1. A radio frequency circuit comprising:
a first filter connected to an antenna connection terminal and having a passband including a first band;
a second filter connected to the antenna connection terminal and having a passband including a second band; and
a first active circuit connected to the first filter, wherein
the first active circuit includes:
a first low noise amplifier;
a first capacitor disposed on a feedback path of the first low noise amplifier; and
at least one of a first inductor or a first resistor, disposed on the feedback path, and
a signal of the first band and a signal of the second band are simultaneously transferable.

2. The radio frequency circuit of claim 1, wherein
the first band is a first time division duplex (TDD) band that is used in TDD,
the second band is a second TDD band that is used in TDD,
the first filter is an LC filter including at least one inductor and at least one capacitor, and
an attenuation amount of the first active circuit in a frequency region between the first band and the second band is larger than an attenuation amount of the first filter in the frequency region.

3. The radio frequency circuit of claim 1, wherein
the first band is a downlink operating band of a first frequency division duplexing (FDD) band that is used in FDD,
the second band is an uplink operating band of a second FDD band that is used in FDD,
the first filter is an acoustic wave filter including at least one acoustic wave resonator, and
the first active circuit has a passband including the downlink operating band.

4. The radio frequency circuit of claim 3, wherein
the first active circuit has an attenuation band including the uplink operating band, and
an attenuation amount of the first filter at a frequency end closer to the first band out of two frequency ends of the second band is larger than the attenuation amount of the first active circuit at the frequency end.

5. The radio frequency circuit of claim 1, wherein
the first band is on a lower-frequency side than the second band,
one of the first filter or the first active circuit is a low-pass filter that includes the first band in a passband and the second band in an attenuation band, and
an other of the first filter or the first active circuit is a high-pass filter that includes the first band in a passband and a band on a lower-frequency side than the first band in an attenuation band.

6. The radio frequency circuit of claim 1, wherein
the first active circuit further includes a first switch disposed on the feedback path between the first low noise amplifier and at least one of the first capacitor, the first inductor, or the first resistor.

7. The radio frequency circuit of claim 6, wherein
in a first mode in which a signal of the first band and a signal of the second band are simultaneously transferred, the first switch is in a conducting state, and
in a second mode in which only a signal of the first band out of the signal of the first band and a signal of the second band is transferred, the first switch is in a non-conducting state.

8. The radio frequency circuit of claim 6, wherein
the first active circuit further includes:
at least one of a second capacitor or a second inductor, disposed on the feedback path; and
a second switch that is disposed on the feedback path between the first low noise amplifier and the at least one of the second capacitor or the second inductor.

9. The radio frequency circuit of claim 8, wherein
a passband of the first filter and a passband of the first active circuit include a third band that overlaps at least partially the first band,
in a first mode in which a signal of the first band and a signal of the second band are transferred simultaneously, the first switch is in a conducting state and the second switch is in a non-conducting state, and
in a third mode in which a signal of the third band and a signal of the second band are transferred simultaneously, the first switch and the second switch are in the conducting state.

10. The radio frequency circuit of claim 1, further comprising:
a second active circuit connected to the second filter, wherein
the second active circuit includes:
a second low noise amplifier;
a third capacitor disposed on a feedback path of the second low noise amplifier; and
at least one of a third inductor or a third resistor, disposed on the feedback path.

11. The radio frequency circuit of claim 1, wherein
the first low noise amplifier, the first capacitor, and the at least one of the first inductor or the first resistor are disposed on a single board or in a single package.

12. The radio frequency circuit of claim 6, wherein
the first low noise amplifier, the first capacitor, the at least one of the first inductor or the first resistor, and the first switch are included in a single semiconductor integrated circuit (IC).

13. The radio frequency circuit of claim 1, further comprising:
a module board including a first principal surface and a second principal surface on opposite sides of the module board, wherein
the first filter and the second filter are disposed on the first principal surface, and
the first active circuit is disposed on the second principal surface.

14. The radio frequency circuit of claim 1, wherein
the first filter, the second filter, and the first active circuit are included in a single semiconductor IC.

15. The radio frequency circuit of claim 2, wherein
the first band is any one of Band 42 for 4th generation (4G)-long term evolution (LTE), n77 for 5th generation (5G)-new radio (NR), or n78 for 5G-NR, and
the second band is n79 for 5G-NR.

16. The radio frequency circuit of claim 3, wherein
the first band and the second band are each any one of Band 5, Band 8, Band 12, Band 13, Band 14, Band 17, Band 20, Band 26, Band 28, Band 71, n5, n8, n12, n13, n14, n17, n20, n26, n28, or n71,
Band 5, Band 8, Band 12, Band 13, Band 14, Band 17, Band 20, Band 26, Band 28, and Band 71 are for 4G-LTE, and
n5, n8, n12, n13, n14, n17, n20, n26, n28, and n71 are for 5G-NR.

17. The radio frequency circuit of claim 6, wherein
the first band is any one of n77 or n78 for 5G-NR, and
the second band is n79 for 5G-NR.

18. The radio frequency circuit of claim 6, wherein
the first band is n46 for 5G-NR, and
the second band is any one of n79, n96, or n97 for 5G-NR.

19. The radio frequency circuit of claim 6, wherein
the first band is any one of n96 or n97 for 5G-NR, and
the second band is n46 for 5G-NR.

20. The radio frequency circuit of claim 9, wherein
the first band is n77 for 5G-NR,
the second band is n79 for 5G-NR, and
the third band is any one of Band 42 for 4G-LTE or n78 for 5G-NR.

21. A communication device comprising:
a signal processing circuit configured to process a radio frequency signal; and
the radio frequency circuit of claim 1 configured to transfer the radio frequency signal between the signal processing circuit and an antenna.
